(19) United States
(12) Patent Application Publication
(10) Pub. No.: US 2008/0083176 A1
(43) Pub. Date: Apr. 10, 2008

(54) Roofing panel

(75) Inventors: Stephan K. Barsun, Davis, CA (US); Richard C. Bourne, Davis, CA (US)

Correspondence Address: OLIFF & BERRIDGE, PLC, P.O. BOX 320850, ALEXANDRIA, VA, 22320-4850, US

(73) Assignee: DAVIS ENERGY GROUP, INC., Davis, CA (US)

(21) Appl. No.: 11/905,960

(22) Filed: Oct. 5, 2007

Related U.S. Application Data
(60) Provisional application No. 60/849,778, filed on Oct. 6, 2006.

(51) Int. Cl. E04D 13/18; H01L 31/042

(52) U.S. Cl. 52/173.3; 52/745.2

(57) ABSTRACT

A roofing panel is provided with a deck having an upper surface that forms a plurality of tubing channels, tubing positioned within the tubing channels, and an upper roofing layer covering the deck, plate layer and tubing. The roofing layer may also have a photovoltaic array panel. The roofing panel may also have a plurality of truss braces, each truss brace being affixed to a lower surface of the deck. In some embodiments, the truss braces are positioned within one of a plurality of truss brace channels formed in a lower surface of the deck. The truss braces have a lower end that terminates in at least one projection extending from a bottom edge of the deck and an upper end forming an opening for slidingly receiving a lower end of a truss brace of an adjacent panel.

### BACKGROUND

This invention relates to roofing materials for residential and commercial buildings, and more specifically, rooftop arrays for use in providing thermal and electrical energy. More specifically, the invention relates to a fully integrated photovoltaic/thermal roofing module.

There is a need to design and build residences that renewably generate such as much energy, both thermal and electrical, as they consume. Building-integrated solar technologies for residential roofing, such are roof-top solar units, have been developed. Conventional solar energy roofing arrays, however, have not been widely used by home builders because these units have not provided the combination of appearance, function, and economics that satisfy new home buyers. Conventional solar energy roofing arrays have also failed to provide installation methods that utilize conventional construction techniques.

### SUMMARY

A rooftop panel is provided including a metal, wooden or polymer support deck forming a plurality of channels on its upper surface, tubing positioned within the channels for use in conveying a heat transfer fluid, and in some embodiments, a roofing layer. The roofing layer, which may include a photovoltaic array, covers an upper surface of the deck above the tubing.

In embodiments, a rooftop panel may include a plurality of truss braces. Utilizing the truss braces, the rooftop panels may be adapted for connection along its bottom edge to the top edge of another, adjacent array. This may include the use of a lower edge flap along the bottom edge of the array to allow sealing the panel to another panel, or alternatively, to the roofing below.

In embodiments, a roofing panel provides structural roofing in addition to electrical and thermal energy for commercial and domestic use and space heating. The roofing panel with truss braces allows the panel to only be fastened along the top edge, reducing installation labor costs. The truss braces interlock adjacent panels.

In embodiments, a method of installing a structural roofing panel to roof trusses is provided where the roofing layer is affixed to the deck only along a top edge of the deck. The method includes positioning a bottom surface of a roofing panel on roof trusses, the roofing panel having a deck with an upper surface that forms a plurality of tubing channels, tubing positioned within the tubing channels, and an upper roofing layer covering the deck, plate layer, if necessary, and tubing.

In embodiments, a method is provided for installing a structural roofing panel to a plurality of roofing trusses. The method includes inserting the lower ends of truss braces of a first roofing panel into corresponding upper ends of truss braces of a second roofing panel. The first and second roofing panels each have a support deck with an upper surface that forms a plurality of tubing channels. Tubing for use in conveying a heat transfer fluid therein is positioned within the tubing channels, and an upper roofing layer covers the deck, tubing and, if necessary, the plate layer.

The first and second panels also include a plurality of truss braces, each truss brace being affixed to a lower surface of the deck. In some embodiments, the truss braces are positioned within of a plurality of truss brace channels formed in a lower surface of the deck. The truss braces have a lower end that terminates in at least one projection extending from a bottom edge of the deck and an upper end forming an opening for slidingly receiving a lower end of a truss brace of an adjacent panel. The method includes fastening the upper ends of the truss braces to the trusses. With this method, only top edge fasteners are used to affix the roofing panel to the trusses.

In embodiments, the method may include unfolding the roofing layer about a top edge of the deck to expose the upper surface of the deck, fastening the deck to the roof trusses, and folding the roofing layer about the top edge of the deck to cover the upper surface of the deck. With this method, conventional fasteners may be used to affix the roofing panel to the trusses, without damaging the roofing layer.

Embodiments of the present invention provide for solar electric, hot water, and roofing in a single assembly. This significantly reduces manufacturing costs by integrating those three functions into an integrated roofing module. Use of the embodiments reduces labor by eliminating the need to install sheeting, felt, shingles, and PV or solar thermal components on top of the roofing panel. Additionally, the embodiments enhance PV performance by cooling the backside of the PV array with water because PV efficiencies rise with lower temperatures.

These and other objects, advantages and salient features are described in or apparent from the following detailed description of exemplary embodiments.

### BRIEF DESCRIPTION OF THE DRAWINGS

Exemplary embodiments will be described with reference to the drawings, wherein like numerals represent like parts, and wherein:

FIG. 1 is a perspective view of an exemplary roofing panel;

FIG. 2 is another perspective view of an exemplary roofing panel;

FIG. 3 is an exploded view of a first embodiment of an exemplary roofing panel;

FIG. 4 is a perspective view of a first embodiment of an exemplary roofing panel;

FIG. 5A is a side sectional view of a first embodiment of an exemplary roofing panel;

FIG. 5B is a front view of a first embodiment of an exemplary roofing panel;

FIG. 6 is a perspective view of a second embodiment of an exemplary roofing panel;

FIG. 7 a side sectional view of a second embodiment of an exemplary roofing panel;

FIG. 8 is another side sectional view of a second embodiment of an exemplary roofing panel;

FIG. 9 is an exploded view of an exemplary roofing panel illustrating the truss braces and a sealing strip;

FIG. 10 is a perspective view of an exemplary roofing panel illustrating the roofing layer in an unfolded state;

FIG. 11 is perspective view of an installed exemplary roofing panel;

FIG. 12 is an exemplary method of installing a roofing panel; and

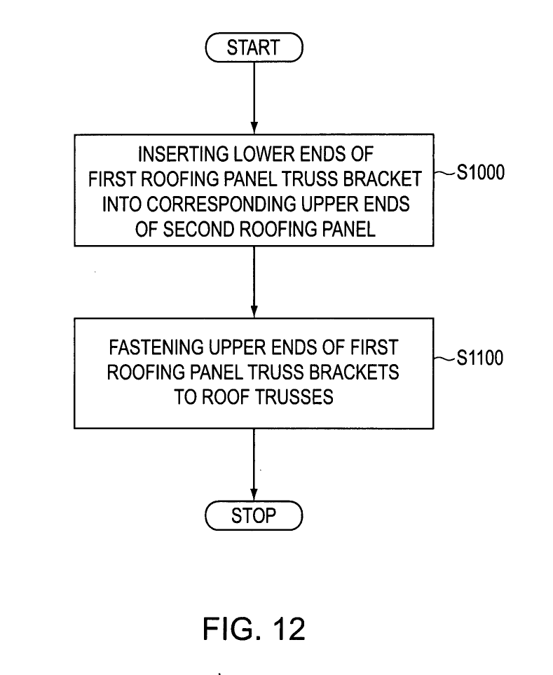

FIG. 13 is another exemplary method of installing a roofing panel.

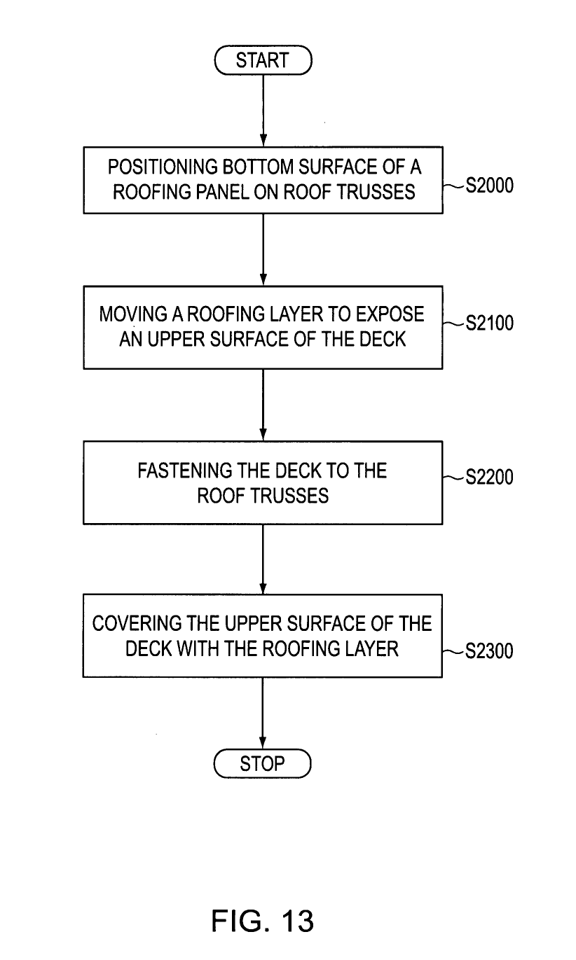

### DETAILED DESCRIPTION OF EMBODIMENTS

In the following description, reference is made to the drawings. In the drawings, like reference numerals have been used throughout to designate identical elements.

A structural roofing panel 10 is provided that spans across roof framing members 12 to form a roofing surface of a commercial or residential building. In embodiments, the roofing panel may be provided with photovoltaic cells for generating solar electrical energy, as well as tubing disposed in the panel for generating thermal energy transferred from the roofing panel 10 by a heat transfer fluid that flows through the tubing. The heat transfer fluid transfers thermal energy from the roofing panel 10 for reuse, and also provides the benefit of cooling the photovoltaic cells, thereby increasing the efficiency of the cells in generating electricity.

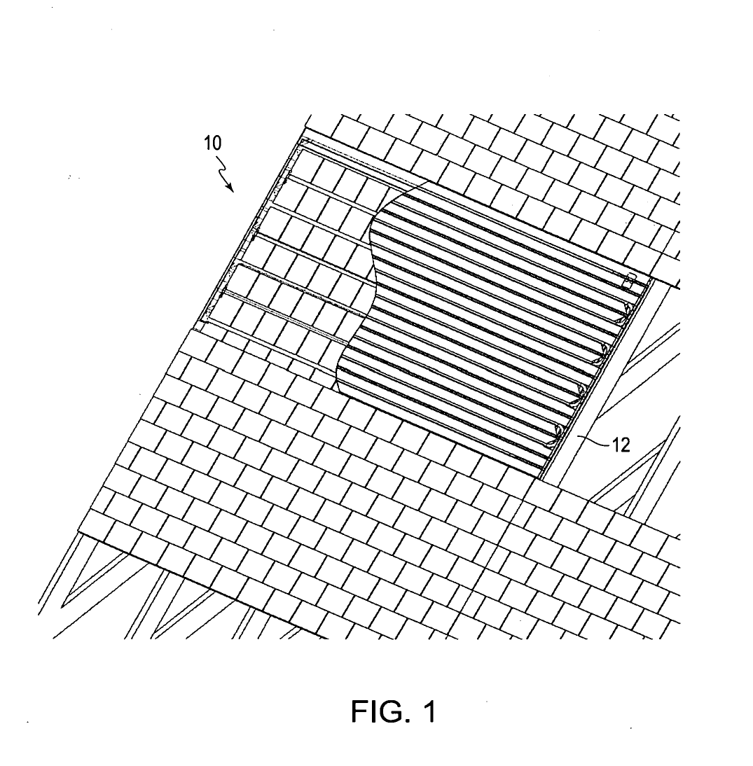

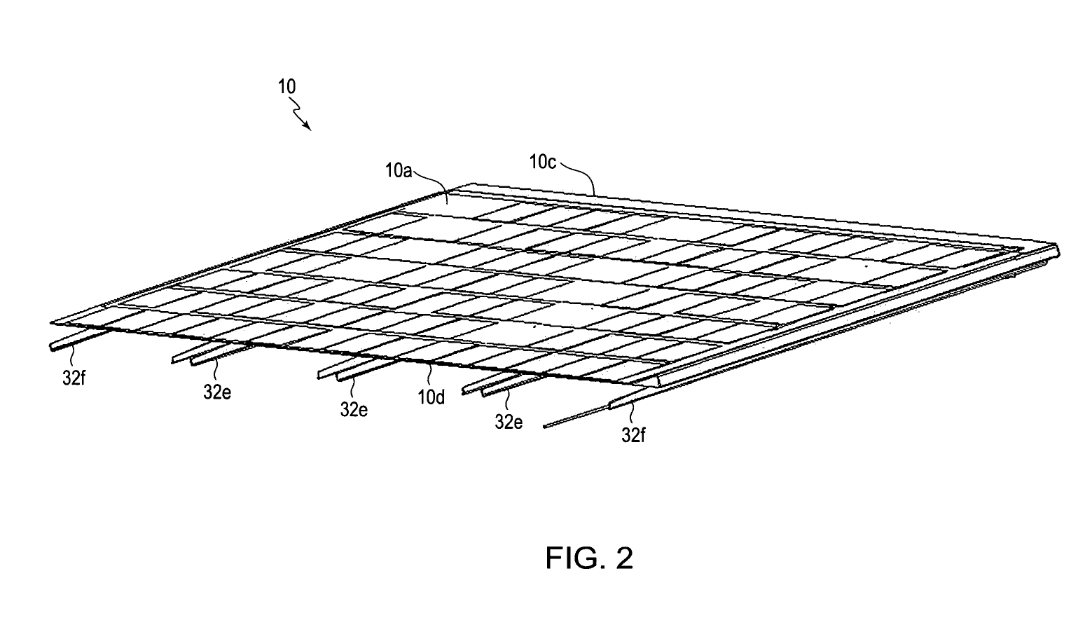

As shown in FIGS. 1 and 2, the roofing panel 10 may replace standard plywood sheets and other conventional roofing materials, thereby significantly reducing installation time and cost compared to conventional methods of mounting photovoltaic and solar thermal panels above the roof surface.

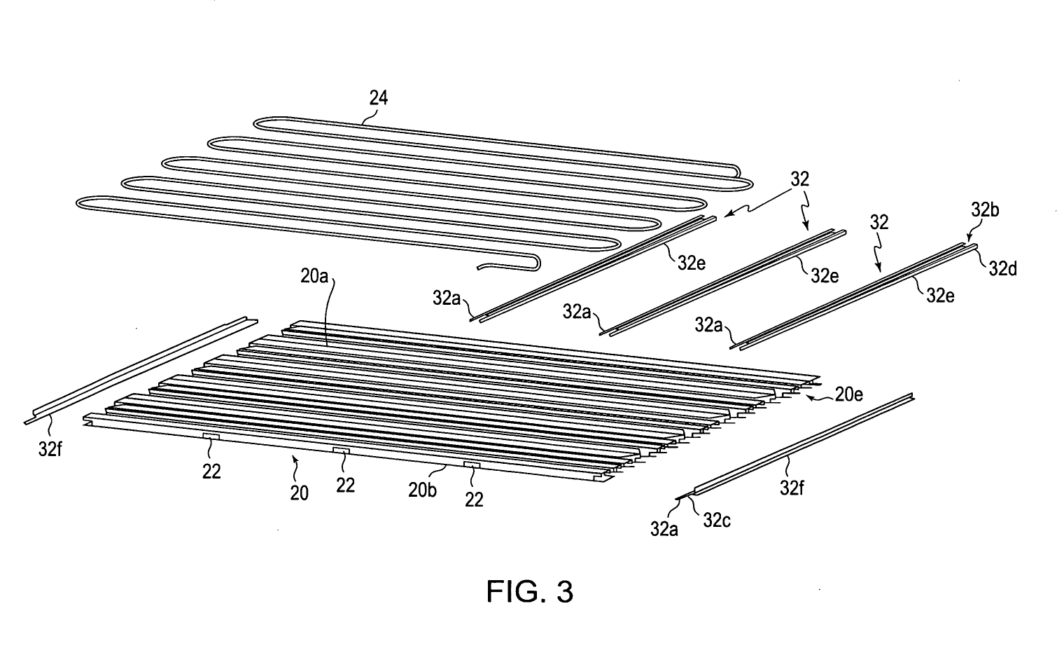

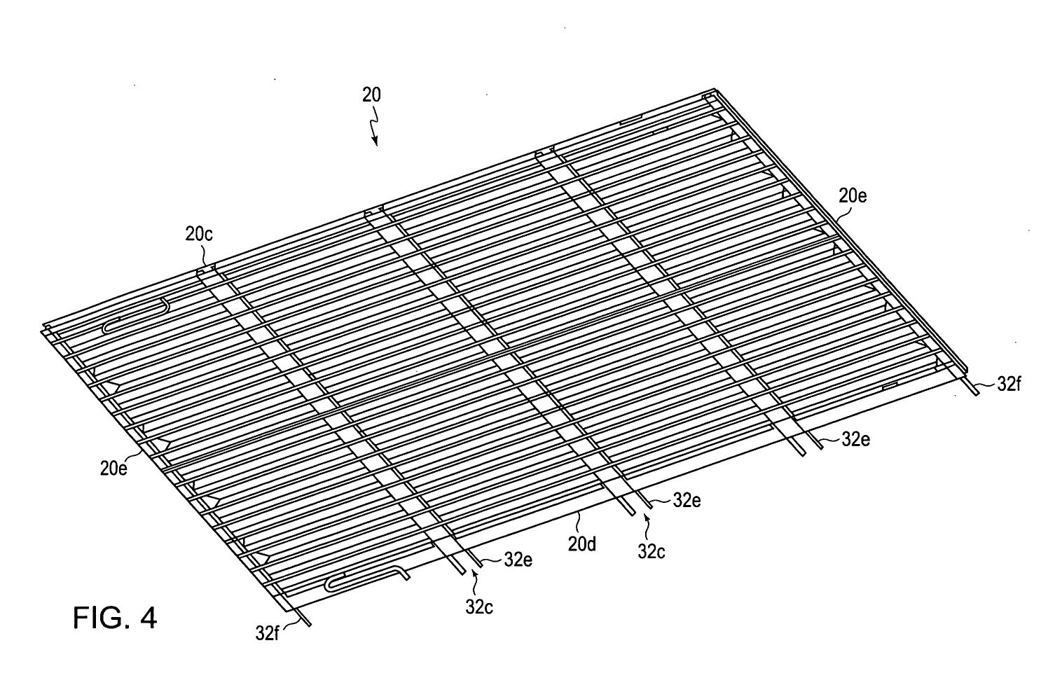

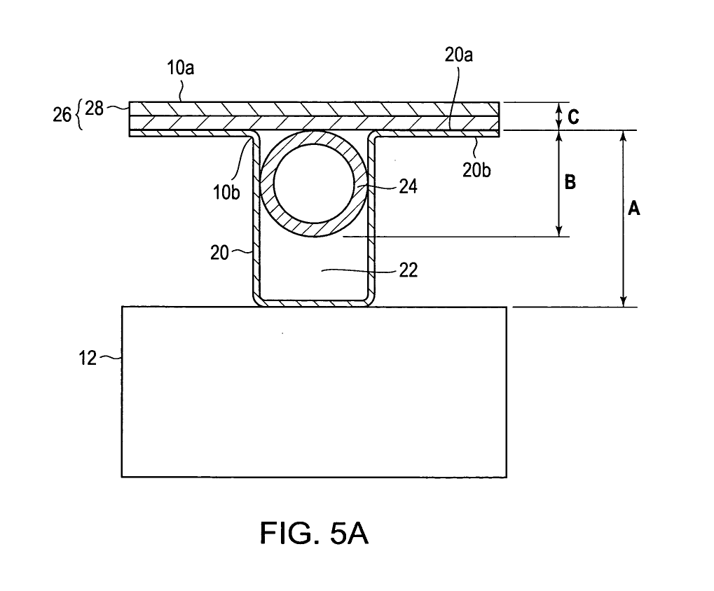

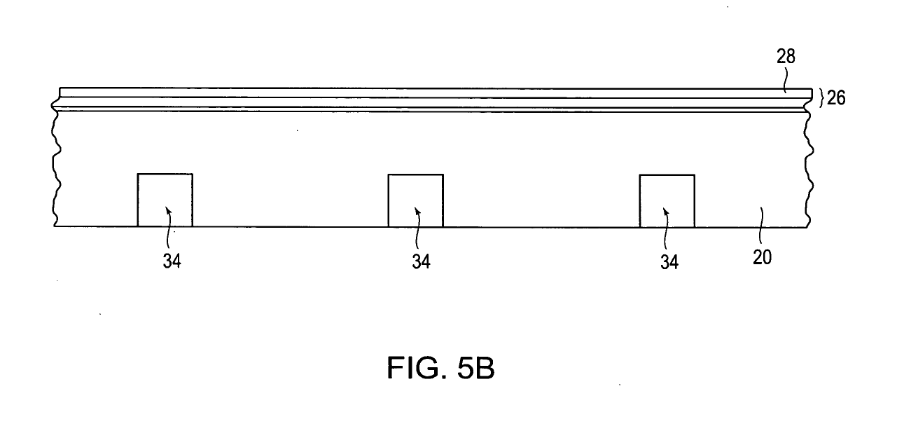

A first embodiment of a structural roofing panel 10, shown in FIGS. 3-5, has a thermally conductive deck 20, such as, for example, a corrugated metal deck with an upper surface 20a, a plurality of tubing channels 22 formed in the upper surface 20a, and tubing 24 (to contain heat transfer fluid such as glycol-based thermal transfer fluid) positioned within the tubing channels 22. The roofing panel also has an upper roofing layer 26, shown in FIG. 5 that covers the deck 20 and tubing 24. In embodiments, the roofing layer 26 may also have a photovoltaic array 28. For purposes of enhancing the generation of electrical and thermal energy, the photovoltaic array 28 is generally provided on an upper surface of the roofing layer 26, and the tubing 24 positioned in close proximity thereto. In some embodiments, the roofing layer 26 is a single-ply material. In other embodiments, the roofing layer may comprise conventional roofing material such as, for example, roofing felt, shingles, or tiles.

The roofing panel 10 provides hot water, electrical power, and structural roofing support to replace the sheeting, felt, and shingles that form conventional roofing, as well as providing thermal and electrical energy. Embodiments of the present invention provide for solar electric, hot water, and roofing in a single roofing panel assembly. This significantly reduces manufacturing costs by integrating those three functions into an integrated roofing module. Use of the embodiments reduces labor by eliminating the need to install sheeting, felt, shingles, and photovoltaic or solar thermal components on top of the roofing panel. Additionally, the embodiments enhance photovoltaic performance by cooling the backside of the photovoltaic array with water because photovoltaic efficiencies rise with lower temperatures.

In the first embodiment, a corrugated deck 20 preferably of aluminum is attached to truss braces 32, also preferably of aluminum. In some embodiments, the corrugated support deck 20 comprises two folded aluminum sheets to form, for example, 4′ wide by 8′ long panels that replace conventional 4′×8′ wood-based roof structural sheets. The corrugations in the support deck 20 provide substantial strength in the long direction, while also providing channels 22 or recesses formed in the upper surface 20a of the deck to securely hold the tubes 24 attached to the upper surface 20a such as by, for example, welding, fastening or adhering. The sides 20e of the deck may be relieved as shown for example, in FIG. 3, with cuts to facilitate return bends in the tubing 24. The deck 20 generally has a thickness A of less than about 2.0 inches, however, larger size decks are contemplated.

Tubing 24, such as comprised of cross linked polyethylene (PEX) or copper is positioned in the channels 22 or ‘valleys’ of the upper surface of the corrugated decking. Although alternate configurations are contemplated, in some embodiments, a length of tubing 24 bent in a serpentine pattern is laid into the channels 22 formed in the upper surface of the corrugated support deck 20. Tubing, via a heat transfer fluid flowing therethrough, extracts heat from the roofing panel 10 surface during solar conditions. The tubing 24 generally has a diameter B of less than about 0.75 inches, however, larger diameter tubing is contemplated.

An upper roofing layer 26, such as, for example in some embodiments, a single ply roofing material is provided with or without photovoltaic cells 28 to cover the deck 20 and tubing 24. In embodiments, the roofing layer 26 may be laminated to the top of the decking 20 and wrapped around the top edge 20c and further adhered to securely fasten the roofing layer 26 along the top edge 20c. Other embodiments supplement the flexible single ply 26 with a photovoltaic cell layer 28 that is laminated to form an upper surface of the roofing layer 26, to provide the roofing panel's source of electrical energy production and in some cases also to provide the panel with a water seal. The photovoltaic array 28 is nominally 4′×8′, but other dimensions based on the specific need as applicable. The roofing layer generally has a thickness C of less than about 0.1 inch, however, thicker roofing layers are applicable.

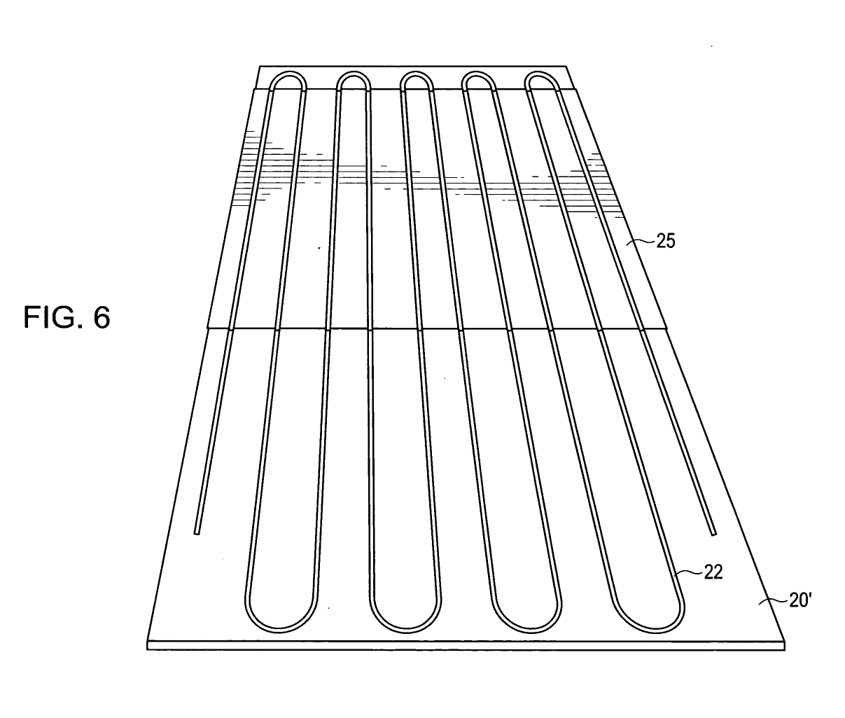

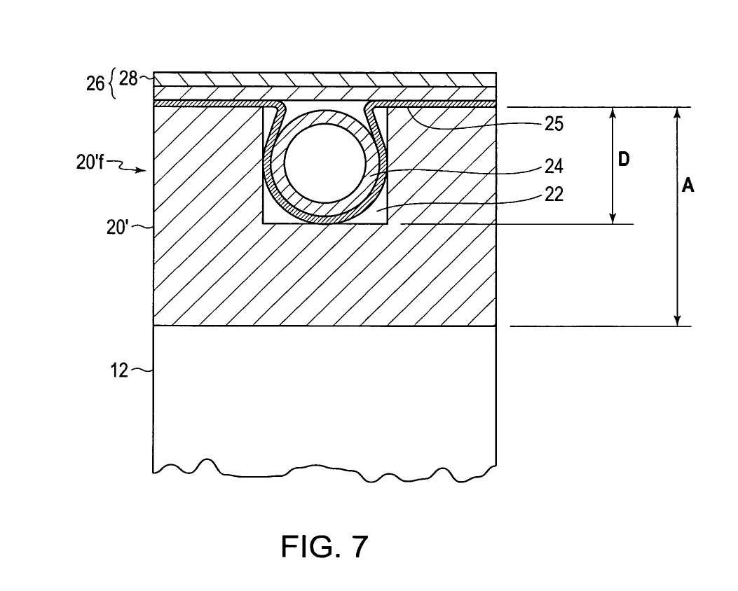

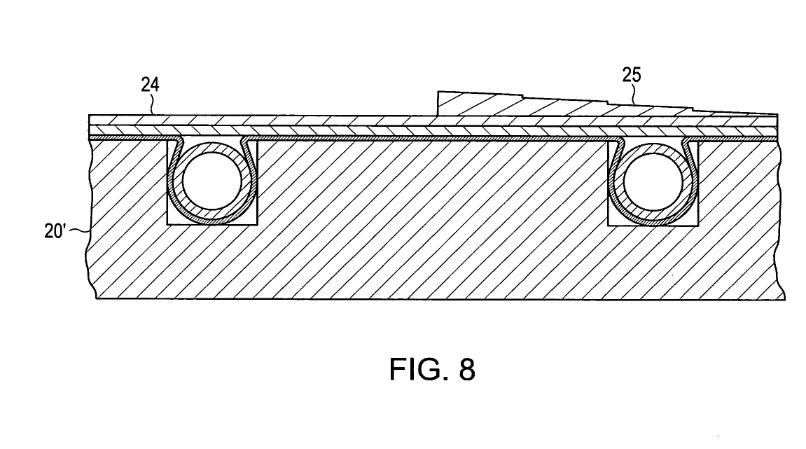

In a second embodiment, shown in FIGS. 6-8, a structural roofing panel 10 is provided with a wooden support deck 20′ a wooden deck having an upper portion 20′f, a thickness D of the upper portion 20′f being less than a thickness A of the deck 20′, and a plurality of tubing channels 22 formed in the upper portion 20′f. Tubing 24 is positioned within the tubing channels 22. Unlike the first embodiment, the second embodiment also has a heat absorber plate layer 25 disposed between the tubing 24 and the deck 20′. The roofing panel 10 may also have an upper roofing layer 26, shown in FIG. 7, that covers the deck 20′, tubing 24 and heat absorber plate 25. In embodiments, the roofing layer 26 may also have a photovoltaic array 28. In some embodiments, the roofing panel is provided with a deck 20′ that does not have a roofing layer 26, so that the roofing panel in this embodiment is limited to providing thermal energy.

In some embodiments, the roofing panel 10 may also include a plurality of truss braces 32, each truss brace being affixed to a lower surface of the deck 20. In some embodiments, the truss braces 32 are optionally positioned within of a plurality of truss brace channels 34 formed in a lower surface of the deck 20.

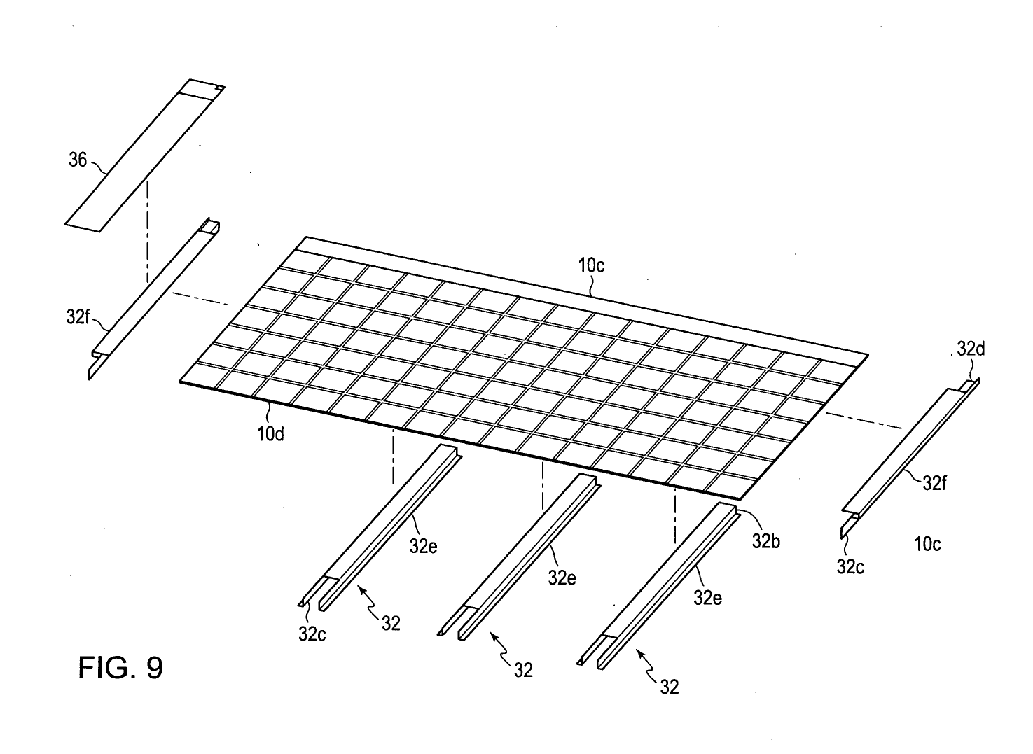

As shown in FIGS. 3, 4 and 9, embodiments of a structural roofing panel 10 include a plurality of truss brace channels 34 formed in a lower surface 20b of the deck 20. The panel 10 may also include a plurality of truss braces 32, each truss brace 32 being affixed to a lower side 20b of the deck and being optionally positioned within one of the truss brace channels 34. In embodiments, the truss brace channels 34 may be configured to slidingly receive the truss braces 32, as shown, for instance, in FIG. 5B. In embodiments, the truss braces have a lower end 32a that terminates in at least one projection 32c extending from a bottom edge 20d of the deck and an upper end 32b forming an opening 32d for slidingly receiving a lower end 32a of a truss brace of an adjacent panel.

In some embodiments, the truss braces 32 are spot welded to the lower surface 20b of the deck, and are fabricated of heavier gauge aluminum. The truss braces 32 may be provided with central braces 32e centrally located within the panel 10, as well as end braces 32f positioned along the sides 20e of the deck. The truss braces 32 stiffen the assembly in the 4′ dimension to withstand wind uplift forces on the panel 10, and reduce the number of field-driven fasteners 14 used to secure the deck 20 to roof trusses 12. The end truss braces 32f also cover the sharp vertical edges of the deck 20 for better handling.

In embodiments a structural roofing panel 10 is provided with a wooden support deck 20′ having a lower support portion 20f. Although different sizes are contemplated, the wooden support deck 20′ generally has a thickness A of less than about 4.0 inches, with an upper portion 20f of the deck having a thickness D of less than about 0.5 inches. In some embodiments, the roofing panel 10 having a wooden deck 20′ may also include a plurality of truss braces 32 affixed to a lower surface of the deck 20.

In embodiments, the panel has a bottom edge 10d that interlocks with a top edge 10c of an adjacent panel. In embodiments, the truss braces 32 are configured to have lower 32a and upper 32b ends that provide an interlocking system.

An exemplary method of installing a structural roofing panel 10 to a plurality of roofing trusses 12 is provided to include inserting S1000 the lower ends 32a of truss braces 32 of a first roofing panel 10 into corresponding upper ends 32b of truss braces 32 of a second roofing panel 10′. The first 10 and second 10′ roofing panels each have a support deck 20 with an upper surface 20a that forms a plurality of tubing channels 22. Tubing 24 for use in conveying a heat transfer fluid therein is positioned within the tubing channels 22, and an upper roofing layer 26 covers the deck 20, tubing 24 and, if necessary, the plate layer 25. The first 10 and second 10′ panels also include a plurality of truss brace channels 34 formed in a lower surface of the deck 20b, and a plurality of truss braces 34, each truss brace 32 being affixed to a lower surface 20a of the deck and being positioned within one of the truss brace channels 34. The truss braces 32 having a lower end 32a that terminates in at least one projection 32c extending from a bottom edge 10d of the deck and an upper end 32b forming an opening 32d for slidingly receiving a lower end 32a of a truss brace of an adjacent panel 10′. The method includes fastening S1100 the upper ends 32a of the truss braces to the trusses 12. With this method, only top edge fasteners 14 are used to affix the roofing panel 10 to the trusses 12.

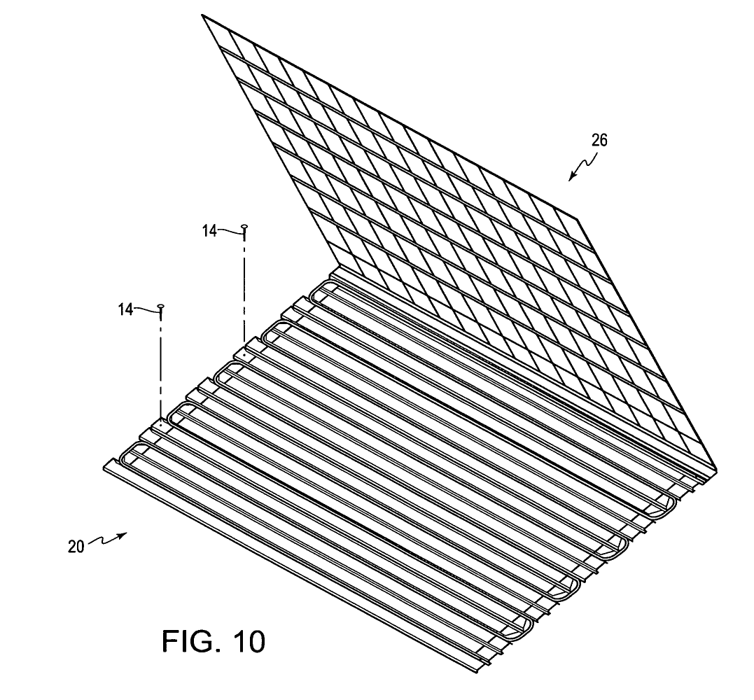

In embodiments, a method of installing a structural roofing panel 10 to roof trusses 12 is provided where the roofing layer 26 is affixed to the deck 20 only along a top edge 10c of the deck. In embodiments, the roofing layer 26 is a rectangular shape having four sides, and the roofing layer 26 is attached to the deck 20 along only one of the sides of the roofing layer 26. The method includes positioning S2000 a bottom surface 10b of a roofing panel on roof trusses 12, the roofing panel 10 having a deck 20 with an upper surface 20a that forms a plurality of tubing channels 22, tubing 24 positioned within the tubing channels 22, and an upper roofing layer 26 covering the deck 20, plate layer 25, if necessary, and tubing 24. The method also includes moving S2100 the roofing layer about the top edge 20c of the deck to expose the upper surface 20a of the deck, as shown in FIG. 10, fastening S2200 the deck 20 to the trusses 12, and moving S2300 the roofing layer 26 about the top edge 20c of the deck to cover the upper surface 20a of the deck. With this method, conventional fasteners 14 may be used to affix the roofing panel 10 to the trusses 12, without damaging the roofing layer 26.

A rooftop array 10 is provided including a corrugated metal or wooden deck 20 forming a plurality of channels 22 on its upper surface, tubing 24 positioned within the channels 22 for use in conveying a heat transfer fluid, and a single ply roofing layer 26, including a photovoltaic array 28, covers an upper surface 20a of the deck above the tubing 24. The embodiments may further comprise a plurality of truss braces 32. The rooftop array 10 may also be adapted for connection along its bottom edge 10d to the top edge 10c of another, adjacent array. This may include the use of a lower edge flap along the bottom edge 10d of the array to allow sealing the panel to another panel, or alternatively, to the roofing 12 below.

The roofing module 10 provides structural roofing in addition to electrical and thermal energy for commercial and domestic use and space heating. The roofing panel 10 with truss braces 32 allows the panel 10 to be fastened only along the top edge 10c, reducing installation labor costs. The truss braces 32 interlock adjacent panels 10. The roofing panel with a single ply cover 26 and a lower edge flap also allows sealing to the panel 10 or roofing 12 below it.

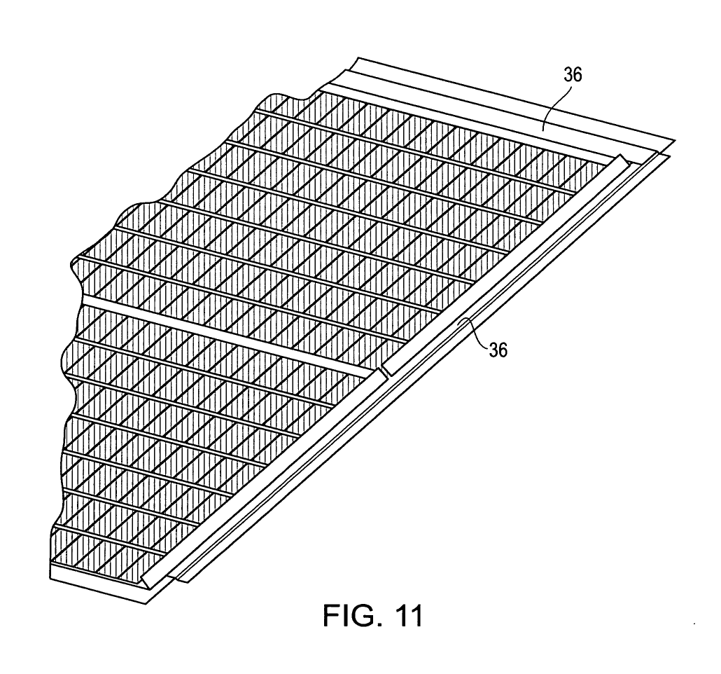

The edges of the roofing panel may be fastened with additional strips 36, as shown in FIG. 11, that are adhered to both the single ply 26 and the decking 20 to secure the bottom edge. Additionally, the bottom edge of the single ply 26 overhangs the panel 10 by a distance, in the preferred embodiment approximately 4 to 5 inches, to allow sealing to an adjacent panel 10 or roofing 12 below. The sides may be sealed with the addition of a sealing single ply strip 36 to provide additional waterproofing. The roofing layer 26 may extend beyond the photovoltaic layer 28 and around a top edge of the 20d deck. The roofing layer 26 may be adhered to the upper surface 20a of the deck. At the lower panel edge 10d, a strip 36 of un-reinforced single ply membrane material may be fused to the roofing layer 26, wrapped around the edge, and adhered to the underside of the deck 20. The panels 10 may include top and bottom folds to allow edge tabs from the single ply roofing material 26 to be wrapped around the top 10c and bottom 10d edges.

In some embodiments, the panels 10 will be held to the roof 12 at the top edge 10c with lag bolts driven into the trusses through prepared, recessed holes at the top edge 10c of the panel at the truss braces 32. These holes can be formed on an angle to avoid engaging the roof layer 26. These holes can be caulked and further sealed by the overlapping roofing layer 26 at the edges of adjacent panels, or by flashing strips 36 used as a transition to adjacent standard roofing materials (shingles, flashing, etc.). The bottom edge 10d of the panels can be held in place by truss brace 34 interlocking, and fastening the lowest panel to the roof 12.

It will be appreciated that various of the above-disclosed and other features and functions, or alternatives thereof, may be desirably combined into many other different systems or applications. Also, various presently unforeseen or unanticipated alternatives, modifications, variations or improvements therein may be subsequently made by those skilled in the art which are also intended to be encompassed by the following claims.

What is claimed is:

1. A structural roofing panel, comprising:
a thermally conductive deck having an upper surface that defines a plurality of tubing channels;
tubing, at least a portion of the tubing positioned within the tubing channels; and
an upper roofing layer covering the deck and tubing.

2. A structural roofing panel as described in claim 1, wherein the roofing layer comprises a photovoltaic array.

3. A structural roofing panel as described in claim 1, wherein the tubing has a serpentine shape.

4. A structural roofing panel as described in claim 1, wherein the thermally conductive deck is comprised of corrugated metal.

5. A structural roofing panel as described in claim 1, wherein the deck has a thickness of less than about 2.0 inches, the tubing has a diameter of less than about 0.75 inches, and the roofing layer has a thickness of less than about 0.1 inch.

6. A structural roofing panel as described in claim 1, wherein the panel has a bottom edge that interlocks with a top edge of an adjacent panel.

7. A structural roofing panel as described in claim 6, further comprising a plurality of truss braces, each truss brace being affixed to a lower side of the deck the truss braces having a lower end that terminates in at least one projection extending from a bottom edge of the deck and an upper end forming an opening for slidingly receiving a lower end of a truss brace of an adjacent panel.

8. A structural roofing panel as described in claim 6, further comprising a plurality of truss braces, each truss brace being slidingly received in a truss brace channel formed in the deck, each truss brace having a lower end that terminates in at least one projection extending from a bottom edge of the deck and an upper end forming an opening for slidingly receiving a lower end of a truss brace of an adjacent panel.

9. A structural roofing panel as described in claim 7, wherein each truss brace is positioned within one of a plurality of truss brace channels formed in a lower portion of the deck.

10. A structural roofing panel as described in claim 1, wherein the roofing layer is a rectangular shape having four sides, the roofing layer being attached to the deck along only one of the sides of the roofing layer.

11. A structural roofing panel as described in claim 1, wherein the roofing layer is affixed to the deck only along a top edge of the deck.

12. A structural roofing panel, comprising:
a deck having an upper portion, a thickness of the upper portion being less than a thickness of the deck, that defines a plurality of tubing channels,
tubing, at least a portion of the tubing positioned within the tubing channels, and
a heat absorber plate layer disposed between the tubing and the deck.

13. A structural roofing panel as described in claim 12, further comprising an upper roofing layer covering the deck, plate layer and tubing.

14. A structural roofing panel as described in claim 13, wherein the roofing layer comprises a photovoltaic array.

15. A structural roofing panel as described in claim 12, wherein the tubing has a serpentine shape.

16. A structural roofing panel as described in claim 12, wherein the deck is comprised of wood.

17. A structural roofing panel as described in claim 12, wherein the roofing layer is a rectangular shape having four sides, the roofing layer being attached to the deck along only one of the sides of the roofing layer

18. A structural roofing panel as described in claim 12, wherein the panel has a bottom edge that interlocks with a top edge of an adjacent panel.

19. A structural roofing panel as described in claim 18, further comprising a plurality of truss braces, each truss brace being affixed to a lower side of the deck and being positioned within one of the truss brace channels, the truss braces having a lower end that terminates in at least one projection extending from a bottom edge of the deck and an upper end forming an opening for slidingly receiving a lower end of a truss brace of an adjacent panel.

20. A structural roofing panel as described in claim 13, wherein the roofing panel further comprises a roofing layer affixed only along to a top edge of the deck.

21. A structural roofing panel as described in claim 13, wherein the deck has a thickness of less than about 2.0 inches, the upper portion of the deck has a thickness of less than about 0.75 inches, and the roofing layer has a thickness of less than about 0.1 inch.

22. A method of installing a structural roofing panel to a plurality of roofing trusses, comprising:
positioning a bottom surface of the roofing panel on the trusses, the roofing panel having a deck with an upper surface that forms a plurality of tubing channels, tubing positioned within the tubing channels, and an upper roofing layer covering the deck, plate layer and tubing, the roofing layer being affixed to the deck only along to a top edge of the deck,
moving the roofing layer to uncover the upper surface of the deck,
fastening the deck to the trusses, and
covering the upper surface of the deck, the plate layer and the tubing with the roofing layer.

23. A method of installing a structural roofing panel to a plurality of roofing trusses, comprising:
inserting the lower ends of truss braces of a first roofing panel into corresponding upper ends of truss braces of a second roofing panel, the first and second roofing panels each having a deck with an upper surface that forms a plurality of tubing channels, tubing positioned within the tubing channels, an upper roofing layer covering the deck, plate layer and tubing, a plurality of truss brace channels formed in a lower surface of the deck, and a plurality of truss braces positioned within one of the truss brace channels, the truss braces having a lower end that terminates in at least one projection extending from a bottom edge of the deck and an upper end forming an opening for slidingly receiving a lower end of a truss brace of an adjacent panel; and
fastening the upper ends of the truss braces to the trusses.

24. A method of installing a structural roofing panel to a plurality of roofing trusses as described in claim 23, wherein the roofing layer is affixed only along to a top edge of the deck, the method further comprising:
moving the roofing layer to uncover the upper surface of the deck,
fastening the deck to the trusses, and
covering the upper surface of the deck, the plate layer and the tubing with the roofing layer.
